(19) United States
(12) Patent Application Publication
(10) Pub. No.: US 2009/0134389 A1
(43) Pub. Date: May 28, 2009

(54) Thin film field effect transistor and electroluminescence display using the same

(75) Inventor: Atsushi Matsunaga, Kanagawa (JP)

Correspondence Address: Moss & Burke, PLLC, 401 Holland Lane, Suite 407, Alexandria, VA, 22314, US

(73) Assignee: FUJIFILM CORPORATION, Minato-ku (JP)

(21) Appl. No.: 12/292,364

(22) Filed: Nov. 18, 2008

(30) Foreign Application Priority Data
Nov. 26, 2007 (JP) 2007-304879
Sep. 26, 2008 (JP) 2008-247625

(51) Int. Cl. H01L 29/22

(52) U.S. Cl. 257/43; 257/E29.094

(57) ABSTRACT

A thin film field effect transistor that has on a substrate, at least a gate electrode, a gate insulating layer, an active layer, a source electrode and a drain electrode, wherein the active layer includes an amorphous oxide, a carrier concentration of the amorphous oxide decreases together with lowering of a temperature thereof from room temperature, and the amorphous oxide has an activation energy of from 0.04 eV to 0.10 eV is provided. A thin film field effect transistor having high mobility and a high ON-OFF ratio, and a high-gradation electroluminescence display using the same are provided.

### CROSS-REFERENCE TO RELATED APPLICATION

This application claims priority under 35 USC 119 from Japanese Patent Application Nos. 2007-304879 and 2008-247625, the disclosures of which are incorporated by reference herein.

### BACKGROUND OF THE INVENTION

1. Field of the Invention

The present invention relates to a thin film field effect transistor and an electroluminescence display using the same. Particularly, it relates to a thin film field effect transistor in which an amorphous oxide semiconductor is used for an active layer, and an electroluminescence display using the same.

2. Description of the Related Art

In recent years, flat panel displays (FPDs) have been put to practical use, due to the progress made in liquid crystal and electroluminescence (EL) technologies, etc. Especially, an organic electroluminescence element (hereinafter sometimes referred to as an “organic EL element”) formed using a thin film material which emits light by excitation due to application of electric current can provide light emission of high brightness at a low voltage, and thus is expected to achieve reduction in device thickness, weight, and size, and power saving, etc. in wide ranging applications including mobile phone displays, personal digital assistants (PDA), computer displays, car information displays, TV monitors, and general illumination.

These FPDs are driven by an active matrix circuit including thin film field effect transistors each using, as an active layer, an amorphous silicon thin film or a polycrystalline silicon thin film provided on a glass substrate. (In the description below, the thin film field effect transistor is sometimes referred to as a “thin film transistor” or “TFT”.)

On the other hand, to make the FPD thinner, lighter, and more resistant to breakage, attempts are being made to use a resin substrate, which is light in weight and flexible, instead of a glass substrate.

However, fabrication of the transistors using the silicon thin films described above requires a thermal treatment process at a relatively high temperature, and it is difficult to form the transistors directly on a resin substrate which is generally low in heat resistance.

Hence, such TFTs have been actively developed using, as a semiconductor thin film, a film of an amorphous oxide, such as an In—Ga—Zn—O-based amorphous oxide, which can be formed at a low temperature, (see, for example, Japanese Patent Application Laid-Open (JP-A) No. 2006-186319 and Thin Solid Films, vol. 486, pages 845-846 (2005)). In particular, it is disclosed in JP-A No. 2006-186319 that better normally-off type transistor characteristics are obtained by the use of an amorphous oxide having an electron carrier concentration of less than 10¹⁸ cm⁻³ for an active layer.

As the films for a TFT made with an amorphous oxide semiconductor can be formed at room temperature, the TFT can be prepared on a film (flexible substrate). Therefore, amorphous oxide semiconductors have been attracting attention as a material for active layers of film (flexible) TFTs lately. Particularly, Prof. Hosono et al. of the Tokyo Institute of Technology have reported that a TFT formed using a-IGZO has a field effect mobility of about 10 cm²/Vs even on a PEN substrate, which is higher than that of an a-Si TFT on glass. Since then, TFTs formed using an amorphous oxide semiconductor have particularly drawn attention, especially as film TFTs. (See for example, NATURE, vol. 432, pages 488-492, Nov. 25, 2004.)

However, in the case of using a TFT formed using a-IGZO, as, for example, a drive circuit of a display, there are the problems in that mobility ranges from 1 cm²/Vs to 10 cm²/Vs, which provides insufficient performance, the OFF current is high, and the ON-OFF ratio is low. In order to obtain a high-gradation image by an active matrix drive circuit using an organic EL element, a TFT which has a high ON-OFF ratio is needed; but under the present circumstances, sufficient gradation is not obtained because the ON-OFF ratio is insufficient. Particularly, in order to apply such a TFT to a display incorporating an organic EL element, further increase in mobility and improvement in ON-OFF ratio are required.

### SUMMARY OF THE INVENTION

The present invention has been made in view of the above circumstances and provides a thin film field effect transistor and an electroluminescence display using the same with the following aspects.

A first aspect of the invention provides a thin film field effect transistor comprising, on a substrate, at least a gate electrode, a gate insulating layer, an active layer, a source electrode and a drain electrode, wherein the active layer comprises an amorphous oxide, a carrier concentration of the amorphous oxide decreases together with lowering of a temperature thereof from room temperature, and the amorphous oxide has an activation energy of from 0.04 eV to 0.10 eV.

A second aspect of the invention provides an electroluminescence display comprising a light-emitting element comprising, between a pair of electrodes, a thin film layer comprising at least a light-emitting layer, and a thin film field effect transistor for driving the light-emitting element, wherein the thin film field effect transistor is the thin film field effect transistor according to the first aspect.

### BRIEF DESCRIPTION OF THE DRAWINGS

FIG. 1 is a schematic diagram showing the structure of a TFT element having a reversed stagger structure according to the invention.

FIG. 2 is a schematic diagram showing the structure of a TFT element having a reversed stagger structure according to another embodiment of the invention.

FIG. 3 is a schematic diagram of an equivalent circuit of an active matrix-driving type organic EL display using the TFT element according to the invention.

### DETAILED DESCRIPTION OF THE INVENTION

It is an object of the invention to provide a thin film field effect transistor which uses an amorphous oxide semiconductor, and exhibits high field effect mobility and a large ON-OFF ratio, and particularly, to provide a high-performance thin film field effect transistor which can be prepared on a flexible substrate.

Also, it is another object of the invention to provide an electroluminescence display which is capable of displaying a high-gradation image, by using the TFT element having a high ON-OFF ratio.

The problems described above have been solved by a thin film field effect transistor having, on a substrate, at least a gate electrode, a gate insulating layer, an active layer, a source electrode and a drain electrode, wherein the active layer contains an amorphous oxide, a carrier concentration of the amorphous oxide decreases together with lowering of a temperature thereof from room temperature, and the amorphous oxide has an activation energy of from 0.04 eV to 0.10 eV.

Preferably, the amorphous oxide is a complex oxide including In and Zn. More preferably, a ratio In/Zn of the number of In atoms contained in the amorphous oxide to the number of Zn atoms contained in the amorphous oxide, is from 0.1 to 4.0.

Preferably, the amorphous oxide further includes Ga. More preferably, the amorphous oxide is a complex oxide of In, Zn and Ga.

Preferably, the carrier concentration of the amorphous oxide at room temperature is 6×10¹³ cm⁻³ or more and less than 6×10¹⁵ cm⁻³.

Preferably, the active layer has at least a first region constituted by the amorphous oxide having an activation energy of from 0.04 eV to 0.10 eV, and a second region constituted by a second amorphous oxide having an activation energy of less than 0.04 eV, wherein the second region is in contact with the gate insulating layer, and the first region is disposed so as to be electrically connected between the second layer and at least one of the source electrode or the drain electrode.

Preferably, the second amorphous oxide is a complex oxide of In, Zn and Ga.

Preferably, a carrier concentration of the second amorphous oxide at room temperature is 6×10¹⁵ cm⁻³ or more and less than 1×10²⁰ cm⁻³.

Preferably, the substrate is a flexible substrate.

An amorphous oxide semiconductor has been attracting attention as a material for an active layer of a film (flexible) TFT, because an amorphous oxide semiconductor film can be formed at room temperature, which allows a TFT to be prepared using a flexible plastic film as a substrate. Particularly, it is reported that a TFT which is formed on a PET film and has good performance such as a field effect mobility of 10 cm²/Vs and an ON-OFF ratio of over 10³ was achieved by using an In—Ga—Zn—O-based oxide in a semiconductor layer (i.e., an active layer). However, when such a TFT is used in a drive circuit of a display, the performance of the TFT is still insufficient with regard to mobility and ON-OFF ratio to operate the drive circuit.

The reason for this is as follows. In the conventional art, in order to reduce the OFF current, it is required that the concentration of electron carriers in the active layer is less than 10¹⁸ cm⁻³. However, an amorphous oxide semiconductor used for the active layer tends to have low electron mobility when the concentration of electron carriers is decreased, so that it has been difficult to form a TFT which can achieve both of good OFF characteristics and high mobility at the same time.

Hence, the inventors have conducted intensive research to find means for increasing the field effect mobility of a TFT and improving the ON-OFF ratio. As a result, there has been found, as an effective means, a configuration of a thin film field effect transistor having at least a gate electrode, a gate insulating layer, an active layer containing an amorphous oxide semiconductor, a source electrode and a drain electrode in this order, wherein the active layer includes the amorphous oxide which tends to decrease in electron carrier concentration together with lowering of a temperature thereof from room temperature, and wherein an activation energy is from 0.04 eV to 0.10 eV. In addition, it has been found that further incorporation of an amorphous oxide that tends to decrease in electron carrier concentration together with lowering of a temperature thereof from room temperature, wherein an activation energy is less than 0.04 eV, attains excellent performance. Thereby, the present invention has been achieved.

According to the invention, a thin film field effect transistor which exhibits high field effect mobility and a large ON-OFF ratio, and an electroluminescence display which uses the thin film field effect transistor and is capable of displaying a high-gradation image are provided. Particularly, a thin film field effect transistor which is useful as a film (flexible) TFT using a flexible substrate and an electroluminescence display using the same are provided.

1. Thin Film Field Effect Transistor

The thin film field effect transistor of the invention is an active element that has at least a gate electrode, a gate insulating layer, an active layer, a source electrode and a drain electrode in this order, and has a function of switching current between the source electrode and the drain electrode, in which the current passing through the active layer is controlled by applying voltage to the gate electrode. Either of a stagger structure or a reversed stagger structure can be formed as the TFT structure. A current that flows through the active layer is proportional to an electric conductivity. The electric conductivity is proportional to a carrier concentration and a carrier mobility of a substance. When the active layer is constituted by an n-type semiconductor, the carrier is an electron, a carrier concentration means an electron carrier concentration, and a carrier mobility means an electron mobility. The thin film field effect transistor of the present invention has a high field effect mobility and exhibits a high ON-OFF ratio. As the result of earnest studies, the inventors have found that a response of inducing carriers in the active layer by voltage applied to the gate electrode (that is, ON-OFF ratio) is not determined only by absolute values of electron carrier concentration, electron mobility and electric conductivity, and that, in particular, a characteristic of variation in electron carrier concentration with temperature, or in other words, an activation energy of the electron carrier concentration, is an important factor. Generally, when increasing a carrier concentration of semiconductors to give a carrier concentration of not less than an effective state density, for n-type semiconductors, the Fermi level exceeds the lowermost level of a conduction band (For p-type semiconductors, the Fermi level falls below the uppermost level of the valence band. The level in this situation represents the electron energy level.). Such semiconductors are referred to as degeneration semiconductors. When the active layer is constituted by an n-type degeneration semiconductor, the carrier is an electron, and an activation energy of the electron carrier concentration is about 0 eV. In the n-type degeneration semiconductor, since carriers are easily induced in the active layer even when an insufficient voltage is applied to the gate electrode, the OFF current value increases to significantly degrade the response (that is, ON-OFF ratio), which is not preferred.

When an activation energy of the electron carrier concentration is greater than 0 eV and less than 0.04 eV, although a response (that is, ON-OFF ratio) is improved as compared with that of the above-described degeneration semiconductor, an OFF current value is still high, which is not preferred. When an activation energy of the electron carrier concentration is greater than 0.10 eV, even if a sufficient voltage is applied to the gate electrode, carriers are hardly induced in the active layer, and an ON current value significantly decreases to degrade the response (that is, ON-OFF ratio), which is not preferred. When an activation energy of the electron carrier concentration is from 0.04 eV to 0.10 eV, the OFF current is low because carriers are not induced in the active layer in a state where an insufficient voltage is applied to the gate electrode, and an ON current is high because carriers are induced in the active layer in a state where a voltage is applied to the gate electrode, whereby an excellent response (that is, ON-OFF ratio) is achieved

It is insignificant, for the active layer in the present invention, to define an absolute value of electron carrier concentration as described in JP-A No. 2006-186319, but it is greatly significant to define a characteristic such that the electron carrier concentration varies with temperature, that is, to define an activation energy of the electron carrier concentration. The active layer according to the invention contains a first amorphous oxide in which an electron carrier concentration of the first amorphous oxide tends to decrease together with lowering of a temperature thereof from room temperature, and which has an activation energy of from 0.04 eV to 0.10 eV. When the activation energy is less than 0.04 eV, an ON-OFF ratio degrades due to increase in the OFF current to make the effect of the invention insufficient, and, when it exceeds 0.10 eV, there occurs such a problem as degradation of TFT transfer characteristics due to low mobility, which are not preferred.

The active layer in the present invention preferably further contains a second amorphous oxide, wherein an electron carrier concentration of the second amorphous oxide tends to decrease together with lowering of a temperature thereof from room temperature, and the second amorphous oxide has an activation energy of less than 0.04 eV. When the activation energy in the second amorphous oxide according to the invention exceeds 0.04 eV, it exhibits properties that are not different from those of the first amorphous oxide, whereby the effects of the second amorphous oxide are not sufficiently exerted.

The first amorphous oxide and the second amorphous oxide in the present invention can be used in a two-layer structure. In this case, preferably, the active layer has at least a first layer composed of an amorphous oxide having an activation energy of from 0.04 eV to 0.10 eV and a second layer composed of an amorphous oxide having an activation energy of less than 0.04 eV, wherein the second layer is in contact with the gate insulating layer, and the first layer is disposed so as to be electrically connected between the second layer and at least one of the source electrode or the drain electrode.

The amorphous oxide in the present invention means oxides for which, in the X-ray diffraction spectrum thereof, halo patterns are observed and no specific diffraction peak is observed.

The amorphous oxide in the present invention is preferably an oxide containing In, more preferably, a complex oxide containing In and Ga, or a complex oxide containing In and Zn, and even more preferably, a complex oxide containing In, Ga and Zn.

The activation energy of the amorphous oxide in the present invention can be controlled to a value within an intended range by at least one of (a) a component pressure of oxygen during a film forming process of the amorphous oxide, (b) a metal composition ratio of the amorphous oxide, (c) a distance and relative position between a target and a substrate upon performing sputtering film formation of the amorphous oxide, (d) a moisture partial pressure during a film forming process of the amorphous oxide, and (e) doping with hydrogen atoms or deuterium atoms, or by combinations thereof.

### 1) Electron Carrier Concentration and Temperature Dependency Thereof (Activation Energy)

The electron carrier concentration of the active layer in the present invention is obtained from an electric conductivity.

The electric conductivity is a physical property which indicates how much electricity a substance can conduct. When the carrier concentration of a substance is denoted by n, a charge elementary quantity is denoted by e, and the carrier mobility is denoted by μ, the electric conductivity σ of the substance is expressed as follows.

σ=neμ

When the active layer is composed of an n-type semiconductor, the carrier is an electron. In this case, the carrier concentration refers to the concentration of electron carriers, and the carrier mobility refers to the electron mobility. Conversely, when the active layer is a p-type semiconductor, the carrier is a hole. In this case, the carrier concentration refers to the concentration of hole carriers, and the carrier mobility refers to the hole mobility.

### <Measuring Method>

The electric conductivity of a film can be determined by measuring the sheet resistance of the film, provided that the thickness of the film is known, and the electron carrier concentration can be calculated from the value of the electric conductivity. Furthermore, the measurement of the electric conductivity is conducted with changing temperature during measurement, draw an Arrhenius diagram, and the activation energy of the electron carrier concentration can be obtained.

The electron carrier concentration in the present invention is determined as the value at 25° C., and the activation energy is determined at the temperature range of from 25° C. to −196° C.

### 2) Structure

A structure of the thin film field effect transistor of the invention is not particularly limited, but either of a stagger construction and a reversed stagger construction which are well known may be formed.

FIG. 1 is a schematic diagram showing an example of the reversed stagger structure of the thin film field effect transistor of the invention. In the case where a substrate 1 is composed of a flexible substrate such as a plastic film or the like, the thin film field effect transistor has an insulating layer 6 disposed on one surface of the substrate 1, and on the insulating layer 6, a gate electrode 2, a gate insulating layer 3, and an active layer 4 are stacked. On the surface of the structure thus constructed, a source electrode 5-1 and a drain electrode 5-2 are disposed.

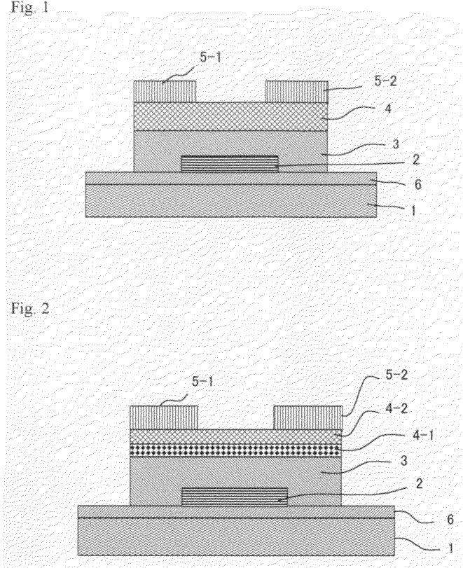

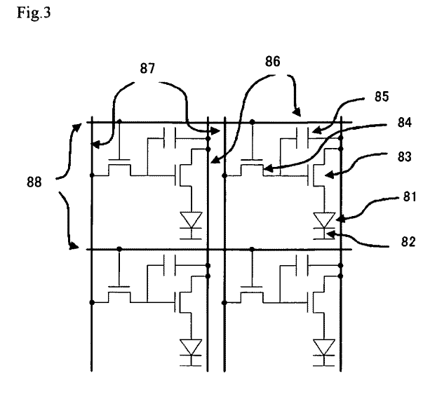

FIG. 2 is a schematic diagram showing another example of the reversed stagger structure. The active layer 4 has two active layers 4-1 and 4-2 laminated in plane, which are different in electric conductivity from each other.

FIG. 3 is a schematic diagram of an equivalent circuit of an active matrix-driving type organic electroluminescence display which uses the thin film field effect transistor of the invention. A schematic circuit diagram of a main part including a switching TFT 84, a driving TFT 83 and an organic EL element 81 are shown. The pixel circuit of the electroluminescence display according to the invention is not particularly limited to that shown in FIG. 3. A circuit which is conventionally known in the art may be applied as-is.

### 3) Gate Insulating Layer

For the gate insulating layer, an insulator such as SiO₂, SiNₓ, SiON, Al₂O₃, Y₂O₃, Ta₂O₅, HfO₂ and the like, or a mixed crystal compound containing at least two of these is used. Also, a polymeric insulator such as polyimide may be used for the gate insulating layer.

It is preferable that the gate insulating layer has a thickness of from 10 nm to 10 μm. To reduce the leak current and raise the voltage resistance, it is required to make the gate insulating layer thicker to a certain extent. However, an increase in the thickness of the gate insulating layer results in a rise in the voltage needed for driving the TFT. Therefore, it is preferable that the thickness of the gate insulating layer is from 50 nm to 1000 nm for an inorganic insulator, and from 0.5 μm to 5 μm for a polymeric insulator. Especially, it is particularly preferable to use an insulator with a high dielectric constant, such as HfO₂, for the gate insulating layer, because then the TFT can be driven with low voltage even when it is made thicker.

### 4) Active Layer

For the active layer used in the invention, it is preferable to use an oxide semiconductor. Particularly, an amorphous oxide semiconductor is preferable. Films of oxide semiconductors, particularly amorphous oxide semiconductors, can be formed at a low temperature, and so can be prepared on a flexible substrate made of a resin such as plastic. Preferable example of the amorphous oxide semiconductors which can be prepared at a low temperature include an oxide containing In, an oxide containing In and Zn, and an oxide containing In, Ga and Zn, as disclosed in JP-A No. 2006-165529. Considering the compositional structures, it is known that amorphous oxide semiconductors of InGaO₃(ZnO)ₘ (m is a natural number less than 6) are preferable. These amorphous oxide semiconductors are n-type semiconductors, in which electrons serve as carriers. Of course, p-type oxide semiconductors such as ZnO/Rh₂O₃, CuGaO₂, and SrCu₂O₂ may be used for the active layer.

Specifically, the amorphous oxide semiconductor according to the invention preferably has a constitution including In—Ga—Zn—O. The amorphous oxide semiconductor is preferably an amorphous oxide semiconductor with a composition of InGaO₃(ZnO)ₘ (m is a natural number less than 6) in a crystalline state. Particularly, InGaZnO₄ is preferable. An amorphous oxide semiconductor of such composition has a feature that electron mobility tends to increase with an increase in electric conductivity. In addition, as to the control of the electric conductivity, it is disclosed in JP-A No. 2006-165529 that the electric conductivity can be controlled by controlling the component pressure of oxygen during film formation.

As a matter of course, not only oxide semiconductors, but also inorganic semiconductors such as Si and Ge, compound semiconductors such as GaAs, and organic semiconductor materials such as pentacene and polythiophene, carbon nanotube, and the like can be used for the active layer.

### <Electron Carrier Concentration of Active Layer>

In the case where the amorphous oxide in the present invention, wherein a carrier concentration decreases along with lowering of temperature, having an activation energy of from 0.04 eV to 0.10 eV, is a complex oxide of In, Zn and Ga, an electron carrier concentration in the active layer is preferably from 1.0×10¹³ cm⁻³ to 1.0×10¹⁶ cm⁻³, and more preferably from 6.0×10¹³ cm⁻³ to 6.0×10¹⁵ cm⁻¹.

Use of the active layer arranged as described above achieves a TFT characterized by an ON-OFF ratio of 10⁶ or higher and high mobility of 10 cm²/Vs or higher.

### <Means for Adjusting Electron Carrier Concentration>

The electron carrier concentration in the active layer according to the invention is controlled by an amorphous oxide contained in the active layer. An amorphous oxide used in the present invention has a tendency to decrease in an electron carrier concentration together with lowering of temperature from room temperature, wherein an activation energy of the electron carrier concentration is from 0.04 eV to 0.10 eV.

As the means for adjusting the electron carrier concentration, the following means are described.

### (1) Adjustment by Oxygen Defect

It is known that when an oxygen vacancy is made in an oxide semiconductor, a carrier electron is generated, which results in an increase in electric conductivity. Hence, the electric conductivity of an oxide semiconductor can be controlled by adjusting the quantity of oxygen vacancies. Specifically, methods for controlling the quantity of oxygen vacancies include adjusting the component pressure of oxygen during film formation, and oxygen concentration and treatment time of an after-treatment after the film formation. Specifically, examples of the after-treatment include heat treatment at a temperature of 100° C. or higher, processing by oxygen plasma, and UV ozone treatment. Among these, the method involving controlling the component pressure of oxygen during film formation is preferable in view of its productivity. It has been disclosed in JP-A No. 2006-165529 that the electron carrier concentration of an oxide semiconductor can be controlled by adjusting the component pressure of oxygen during film formation, and therefore this method is usable.

### (2) Adjustment by Composition Ratio

It has been known that the electric conductivity can be changed by changing the composition ratio of metals of an oxide semiconductor. For instance, it has been disclosed in JP-A No. 2006-165529 that in the case of InGaZn₁₋ₓMgₓO₄, the electric conductivity lowers with an increase in the percentage of Mg. In addition, it has been reported that the electric conductivity of oxides of (In₂O₃)₁₋ₓ(ZnO)ₓ lowers with an increase in the percentage of Zn when the Zn/In ratio is 10% or higher (“TOMEI DOUDENMAKU NO SINTENKAI II (Developments of Transparent Conductive Films II)”, pages 34-35, CMC Publishing CO., LTD.). Preferably, the amorphous oxide in the present invention is an oxide comprising In, more preferably a complex oxide comprising In and Ga, or a complex oxide comprising In and Zn, and even more preferably a complex oxide comprising In, Ga and Zn. In the invention, a ratio of atom of In to Zn (In/Zn) in atom number, with respect to In and Zn contained in the amorphous oxide, is preferably from 0.1 to 4.0, and more preferably from 0.2 to 2.0.

Specifically, methods for changing the composition ratio, for example in the case of a method of forming a film by sputtering, include a method using targets with different composition ratios. Alternatively, multiple targets may be co-sputtered, changing the composition ratio of the resultant film by individually adjusting the sputtering rates for the targets.

### (3) Adjustment by Impurities

It has been disclosed in JP-A No. 2006-165529 that when elements such as La, Na, Mn, Ni, Pd, Cu, Cd, C, N, and P are selectively added to an oxide semiconductor as an impurity, the concentration of electron carriers can be reduced, and therefore the electric conductivity can be made lower. Methods for adding an impurity include co-vapor deposition of the oxide semiconductor and the impurity, and ion-doping of an oxide semiconductor film which has already been formed with ions of the impurity element.

(4) Control by Distance and Relative Position Between Target and Substrate upon Performing Sputtering Film Formation

In the case where a target and a substrate are placed in a vertical alignment with each other, and a distance therebetween is more decreased upon performing sputtering film formation, damage caused by the sputtering becomes larger, and oxygen defects tend to generate easily to result in a larger electric conductivity. Inversely, in the case where a target and a substrate are placed in an offset alignment with each other, and a distance therebetween is more increased, a damage caused by the sputtering becomes smaller, and oxygen defects hardly tend to generate to result in a smaller electric conductivity.

(5) Control by Moisture Partial Pressure upon Film-Forming Amorphous Oxide

In the case where a moisture partial pressure upon performing sputtering film formation of the amorphous oxide is high, damage due to the sputtering is smaller, and oxygen defects hardly generate to result in a small electric conductivity. Inversely, in the case where a moisture partial pressure upon performing sputtering film formation is low, damage due to the sputtering is larger, and oxygen defects tend to generate easily to result in a larger electric conductivity.

### (6) Control by Doping of Hydrogen Atoms or Deuterium Atoms

A carrier concentration can be controlled by doping of hydrogen atoms or deuterium atoms upon performing a sputtering film formation. Specifically, the sputtering film formation is performed in a mixed atmosphere of argon gas, oxygen gas and hydrogen gas.

### (7) Adjustment by Oxide Semiconductor Material

While in the above (1) to (6), the methods of adjusting the electric conductivity of the same oxide semiconductor system have been described, the electric conductivity can be changed by changing the oxide semiconductor material. It is known that the electric conductivity of SnO₂-based oxide semiconductors is lower than the electric conductivity of In₂O₃-based oxide semiconductors. In this way, the electric conductivity can be adjusted by changing the oxide semiconductor material.

As the means for adjusting the electric conductivity, the methods stated in the above (1) to (7) may be used independently or in combination.

For example, the amorphous oxide, wherein an electron carrier concentration of the first amorphous oxide tends to decrease together with lowing temperature from room temperature, having an activation energy of from 0.04 eV to 0.10 eV, is preferably prepared under conditions described below.

The metal composition ratio is preferably In:Ga:Zn=1:0.5 to 5.0:0.25 to 10.0, more preferably In:Ga:Zn=1:1.0 to 5.0:0.25 to 10.0. The component pressure of oxygen is preferably from 0.01 Pa to 0.5 Pa, and more preferably from 0.02 Pa to 0.2 Pa. The moisture partial pressure is preferably from 1.0×10⁻⁵ Pa to 1.0×10⁻¹ Pa, and more preferably from 5.0×10⁻⁵ Pa to 5.0×10⁻⁴ Pa.

On the other hand, the second amorphous oxide, wherein an electron carrier concentration of the second amporphous oxide tends to decrease together with lowering of temperature from room temperature, having an activation energy of less than 0.04 eV, is preferably prepared under conditions described below.

A metal composition ratio is preferably In:Ga:Zn=1:0 to 2.0:0.25 to 10.0, and more preferably, In:Ga:Zn=1:0 to 1.0:0.25 to 10.0. A component pressure of oxygen is preferably from 0.0005 Pa to 0.2 Pa, more preferably from 0.001 Pa to 0.1 Pa. The moisture partial pressure is preferably from 1.0×10⁻⁷ Pa to 1.0×10⁻³ Pa, and more preferably from 5.0×10⁻⁷ Pa to 5.0×10⁴ Pa.

The Ga content in the metal composition ratio of the first amorphous oxide is, preferably, larger than the Ga content in the metal composition ratio of the second amorphous oxide by 0.1 or more.

More preferably, the component pressure of oxygen of the first amorphous oxide is higher by one order of magnitude or more than the component pressure of oxygen of the second amorphous oxide. The moisture partial pressure of the first amorphous oxide is higher by one order of magnitude or more than the moisture partial pressure of the second amorphous oxide.

### <Method of Forming Active Layer>

As the methods for forming a film of the active layer, it is suitable to adopt a vapor-phase film forming method using, as a target, a polycrystalline sintered body of an oxide semiconductor. Among the vapor-phase film forming methods, sputtering method and pulsed laser deposition method (PLD method) are adequate. For mass production, sputtering method is preferable.

For instance, by an RF magnetron sputtering deposition method, a film can be formed while controlling the vacuum level and flow rate of oxygen. The higher the flow rate of oxygen is, the lower the electric conductivity can be made.

It can be verified by conventional X-ray diffraction that the resultant film is an amorphous film.

The thickness of the film can be determined by contact stylus-type surface profile measurement. The composition ratio can be determined by RBS analysis (Rutherford Backscattering Spectrometry).

### 5) Gate Electrode

According to the invention, the following materials are among those which are preferable for the gate electrode: a metal such as Al, Mo, Cr, Ta, Ti, Au or Ag, an alloy such as Al—Nd or APC; a metal oxide electrically conductive film of e.g., tin oxide, zinc oxide, indium oxide, indium-tin oxide (ITO), or indium-zinc oxide (IZO); an organic electrically conductive compound such as polyaniline, polythiophene, or polypyrrole; or a mixture thereof.

The thickness of the gate electrode is preferably from 10 nm to 1000 nm.

The method of forming the gate electrode is not particularly limited. The gate electrode can be formed on the substrate according to a method which is appropriately selected from among wet methods such as a printing method and a coating method, physical methods such as a vacuum deposition method, a sputtering method and an ion plating method, chemical methods such as a chemical vapor deposition (CVD) and plasma CVD method, and the like in consideration of the suitability to the material described above. For example, when ITO is selected, the gate electrode can be formed according to a direct current (DC) or high frequency sputtering method, a vacuum deposition method, or an ion plating method. Further, in the case where an organic electrically conductive compound is selected as the material of the gate electrode, the film formation of gate electrode can be performed according to a wet film-forming method.

### 6) Source Electrode and Drain Electrode

According to the invention, the following are suitable for the material of the source electrode and the drain electrode: metals such as Al, Mo, Cr, Ta, Ti, Au and Ag; alloys such as Al—Nd and APC; metal oxide electrically conductive films of, for example, tin oxide, zinc oxide, indium oxide, indium-tin oxide (ITO) and indium-zinc oxide (IZO); and organic electrically conductive compounds such as polyaniline, polythiophene and polypyrrole, and mixtures thereof.

The thickness of the source electrode and the drain electrode is preferably from 10 nm to 1000 nm.

The method of forming the source electrode and the drain electrode is not particularly limited. The electrodes can be formed on the substrate according to a method which is appropriately selected from among wet methods such as a printing method and a coating method, physical methods such as a vacuum deposition method, a sputtering method and an ion plating method, chemical methods such as a CVD and plasma CVD method, and the like in consideration of the suitability to the material described above. For example, when ITO is selected, the films can be formed according to a DC or high-frequency sputtering method, a vacuum deposition method, an ion plating method, etc. Further, in the case where an organic electrically conductive compound is selected as the material of the source electrode and the drain electrode, the film formation of the source electrode and the drain electrode can be performed according to a wet film-forming method.

### 7) Substrate

According to the invention, the substrate used herein is not particularly limited. The following materials are for example suitable for the substrate: inorganic materials such as YSZ (zirconia stabilized yttrium) and glass; and organic materials including polyesters such as polyethylene terephthalate, polybutylene terephthalate and polyethylene naphthalate, and synthetic resins such as polystyrene, polycarbonate, polyether sulfone, polyarylate, allyl diglycol carbonate, polyimide, polycycloolefin, norbornene resin, and polychlorotrifluoroethylene. In the case of the organic materials described above, a material superior in heat resistance, stability of dimension, resistance to solvents, electric insulating property, workability, low gas permeability, low hygroscopicity, and the like is preferable for the substrate.

According to the invention, it is particularly preferable to use a flexible substrate. As for the material used for the flexible substrate, an organic plastic film which has high transmittance is preferable. For instance, the following materials can be used: polyesters such as polyethylene terephthalate, polybutylene phthalate and polyethylene naphthalate; and plastic films such as polystyrene, polycarbonate, polyether sulfone, polyarylate, polyimide; polycycloolefin, norbornene resin, and polychlorotrifluoroethylene. Also, it is preferable that such film-shaped plastic substrate has an insulating layer in the case where the insulation is insufficient, a gas-barrier layer for preventing moisture and oxygen from penetrating through the substrate, or an undercoat layer for enhancing planarity and adhesion with the electrode or active layer of the film-shaped plastic substrate.

It is preferable that the thickness of the flexible substrate is from 50 μm to 500 μm. The reason for this is that when the thickness of the flexible substrate is less than 50 μm, it is hard for the substrate to maintain sufficient planarity itself, and when the flexible substrate is thicker than 500 μm, it becomes difficult to bend the substrate itself freely, i.e., the flexibility of the substrate becomes insufficient.

### 2. Electroluminescence Display

The thin film field effect transistor of the invention is preferably used for an image display with a liquid crystal or EL element incorporated therein, and particularly for a flat panel display (FPD). More preferably, it is used for a flexible display in which a flexible substrate such as an organic plastic film is used as its substrate. Particularly, the thin film field effect transistor of the invention has high mobility and a high-ON-OFF ratio, and therefore it is most preferably used for a high-gradation electroluminescence display using an organic EL element, or a flexible electroluminescence display.

### (Applications)

The thin film field effect transistor of the invention can be used in an image display with a liquid crystal or EL element incorporated therein, and especially it can be used as a switching element or a driving element of an FPD. It is suitable to use the thin film field effect type transistor as a switching element or a driving element of a flexible FPD device. Further, a display incorporating the thin film field effect transistor of the invention has such wide ranging applications as a mobile phone display, a personal digital assistant (PDA), a computer display, a car information display, a TV monitor, and general illumination.

In addition to electroluminescence displays, the thin film field effect transistor of the invention can be applied extensively to e.g., IC cards, and ID tags, in which the thin film field effect transistor is formed on a flexible substrate such as an organic plastic film.

All publications, patent applications, and technical standards mentioned in this specification are herein incorporated by reference to the same extent as if each individual publication, patent application, or technical standard was specifically and individually indicated to be incorporated by reference.

### EXAMPLES

In the following, the thin film field effect transistor of the present invention will be explained by examples thereof, but the invention is by no means limited by such examples.

### Example 1

### 1. Preparation of Active Layer

(Preparation of Amorphous Oxide)

<Condition 1>

Using a polycrystalline sintered body having a composition of InGaZnO₄ as a target, RF magnetron sputtering vacuum deposition was performed in the presence of argon gas (Ar), while maintaining the total pressure of gas of 0.37 Pa and component pressure of oxygen (O₂) of 0.0005 Pa, under a condition of RF power of 200 W. During the process, the moisture partial pressure was 1.0×10⁻⁴ Pa. As a substrate, a non-alkali glass substrate ((#1737, manufactured by Corning) was used. The center of gravity of the substrate was located at 90 nm just above the center of gravity of the target. The line connecting the center of gravity of the substrate plane and the center of gravity of the target plane had an angle of 90° against the target plane.

<Condition 2>

Deposition was performed under similar conditions to those in the Condition 1 except that the partial pressure of O₂ was changed to 0.001 Pa.

<Condition 3>

Deposition was performed under similar conditions to those in the Condition 1 except that the partial pressure of O₂ was changed to 0.03 Pa.

<Condition 4>

Deposition was performed under similar conditions to those in the Condition 1 except that the partial pressure of O₂ was changed to 0.15 Pa.

<Condition 5>

Deposition was performed under similar conditions to those in the Condition 1 except that the partial pressure of O₂ being 0.0005 Pa was changed to 0.0001 Pa.

<Condition 6>

Using a polycrystalline sintered body having a composition of InGaZn_{0.2}Mg_{0.8}O₄ as a target, RF magnetron sputtering vacuum deposition was performed in the presence of Ar gas, while maintaining the total pressure of gas of 0.40 Pa and partial pressure of O₂ of 0.05 Pa, under a condition of RF power of 200 W.

<Condition 7>

Using a polycrystalline sintered body having a composition of InGaMgO₄ as a target, RF magnetron sputtering vacuum deposition was performed in the presence of Ar gas, while maintaining the total pressure of gas of 0.41 Pa and partial pressure of O₂ of 0.21 Pa, under a condition of RF power of 200 W.

<Condition 8>

Using a target having a composition of In₂O₃:ZnO=90:10 (by weight ratio) (manufactured by Idemitsu Kosan Co., Ltd.), RF magnetron sputtering vacuum deposition was performed in the presence of Ar gas, while maintaining the total pressure of gas of 0.37 Pa and partial pressure of O₂ of 0.037 Pa, under a condition of RF power of 200 W.

<Condition 9>

Using a target having a composition of In₂O₃:ZnO=90:10 (by weight ratio) (manufactured by Idemitsu Kosan Co., Ltd.), RF magnetron sputtering vacuum deposition was performed in the presence of Ar gas, while maintaining the total pressure of gas of 0.37 Pa and partial pressure of O₂ of 0.061 Pa, under a condition of RF power of 200 W.

<Condition 10>

Using a target having a composition of In₂O₃:ZnO=90:10 (by weight ratio) (manufactured by Idemitsu Kosan Co., Ltd.), RF magnetron sputtering vacuum deposition was performed in the presence of Ar gas, while maintaining the total pressure of gas of 0.37 Pa and partial pressure of O₂ of 0.105 Pa, under a condition of RF power of 200 W.

<Condition 11>

In the Condition 1, the center of gravity of the substrate was located to be declined at 103.9 mm (=90 nm/sin 60°) to the center of gravity of the target. The line connecting the center of gravity of the substrate plane and the center of gravity of the target plane had an angle of 60° against the target plane.

<Condition 12>

In the Condition 1, the center of gravity of the substrate was located to be declined at 127.3 mm (=90 cm/sin 45°) to the center of gravity of the target. The line connecting the center of gravity of the substrate plane and the center of gravity of the target plane had an angle of 45° against the target plane.

<Condition 13>

In the Condition 1, the moisture partial pressure was changed to 1.0×10⁻³ Pa.

<Condition 14>

In the Condition 1, the moisture partial pressure was changed to 1.0×10⁻² Pa.

Samples for measurement of physical properties were prepared by depositing the amorphousoxide, which is prepared according to each of the Condition 1 to Condition 14 described above, directly on a non-alkali glass substrate (#1737, manufactured by Corning) at a thickness of 100 nm. The samples for measurement of physical properties were analyzed by a conventional X-ray diffraction method. As a result, it was verified that the resultant layers were amorphous layers. Electric conductivity, carrier concentration by a Hall effect measurement method, and composition ratio of each sample for measurement of physical properties were measured. The obtained results are shown in Table 1.

—Method of Measuring Electric Conductivity—

The electric conductivity of the sample for measurement of physical properties was determined by calculation based on measured sheet resistance and film thickness of the sample. Herein, when the sheet resistance is expressed by ρ (Ω/□), and the film thickness is expressed by d (cm), the electric conductivity σ (Scm⁻¹) is calculated by the equation σ1/(ρ×d).

In the Example, under an environment of 25° C., the measurement was executed by a Loresta GP (manufactured by Mitsubishi Chemical Corp.) for a region of the samples for measurement of physical properties with sheet resistance less than 10⁷Ω/□, and the measurement was executed by a Hiresta UP (manufactured by Mitsubishi Chemical Corp.) for a region of sheet resistance of 10⁷Ω/□ or more. For measurement of film thickness of the sample for measurement of physical properties, a contact stylus-type surface profiler DekTak-6M (manufactured by ULVAC, Inc.) was used.

Further, the measurement was executed at a measurement temperature of 0° C., −100° C., and −196° C.

—Measurement of Carrier Concentration by Hall Effect Measurement Method—

The carrier concentration of the sample for measurement of physical properties was determined by executing Hall effect measurement using a ResiTest 8300 (manufactured by Toyo Corporation). The Hall effect measurement was executed under an environment of 25° C. By the Hall effect measurement, not only the carrier concentration but also the hole mobility of carrier can be determined. Further, an activation energy of the carrier concentration can be calculated by dependency of the carrier concentration on measurement temperature.

—Method of Measuring Activation Energy of Carrier Concentration—

The activation energy of the carrier concentration was calculated by the dependency of the carrier concentration on measurement temperature.

The obtained results of electron carrier concentration and activation energy are shown in Table 1.

As is clear in Table 1, the activation energy of carrier concentration of the amorphous oxide prepared according to the Condition 3, 6, 8, 9, 11, or 13 is within a range of from 0.04 eV to 0.1 eV. Concerning the Condition 1, 2, and 5, the activation energy is less than 0.04 eV; and concerning the Condition-4, 7, 10, 12, and 14, the activation energy exceeds 0.1 eV.

TABLE 1

| | | | Carrier | Activation | Ids | | | |
|---|---|---|---|---|---|---|---|---|
| | | | Concentration | Energy | (Vgs = 0) | Mobility | Surface | |
| No. | Material for Active Layer | Structure | (cm⁻³) | (ΔE/eV) | (A) | (cm²/Vs) | Evenness | Note |
| 1 | InGaZnO₄ | Amorphous | 2.0 × 10¹⁸ | about 0 | 5 × 10⁻⁷ | 13 | 2 | Comparative |
| 2 | InGaZnO₄ | Amorphous | 6.9 × 10¹⁵ | 0.0352 | 4 × 10⁻⁹ | 3 | 3 | Comparative |
| 3 | InGaZnO₄ | Amorphous | 5.0 × 10¹⁵ | 0.041 | 2 × 10⁻¹¹ | 1.5 | 4 | Invention |
| 4 | InGaZnO₄ | Amorphous | 5.0 × 10¹³ | 0.124 | 9 × 10⁻⁹ | 0.15 | 1 | Comparative |
| 5 | InGaZnO₄ | Amorphous | 2.0 × 10¹⁹ | about 0 | 1 × 10⁻⁶ | 13.5 | 3 | Comparative |
| 6 | InGaZn_{0.2}Mg_{0.8}O | Amorphous | 3.0 × 10¹⁶ | 0.051 | 4 × 10⁻¹¹ | 5.3 | 4 | Invention |
| 7 | InGaMgO₄ | Amorphous | 8.0 × 10¹⁴ | 0.11 | 2 × 10⁻¹¹ | 0.8 | 3 | Comparative |
| 8 | In₂O₃—ZnO (90:10) | Amorphous | 3.0 × 10¹⁸ | 0.043 | 3 × 10⁻¹¹ | 25 | 4 | Invention |
| | (by weight ratio) | | | | | | | |
| 9 | In₂O₃—ZnO (90:10) | Amorphous | 1.1 × 10¹⁸ | 0.058 | 2 × 10⁻¹¹ | 10 | 4 | Invention |
| | (by weight ratio) | | | | | | | |
| 10 | In₂O₃—ZnO (90:10) | Amorphous | 6.0 × 10¹⁶ | 0.108 | 2 × 10⁻¹¹ | 0.8 | 3 | Comparative |
| | (by weight ratio) | | | | | | | |
| 11 | InGaZnO₄ | Amorphous | 7.0 × 10¹⁴ | 0.058 | 6 × 10⁻¹¹ | 1.3 | 4 | Invention |
| 12 | InGaZnO₄ | Amorphous | 3.0 × 10¹³ | 0.135 | 1 × 10⁻⁷ | 0.12 | 1 | Comparative |
| 13 | InGaZnO₄ | Amorphous | 4.0 × 10¹⁵ | 0.051 | 5 × 10⁻¹¹ | 1.5 | 4 | Invention |
| 14 | InGaZnO₄ | Amorphous | 2.0 × 10¹³ | 0.151 | 2 × 10⁻⁷ | 0.09 | 1 | Comparative |

### 2. Preparation of TFT Element

As a substrate, a non-alkali glass substrate ((#1737, manufactured by Corning) was used. The substrate was subjected to ultrasonic cleaning with pure water for 15 minutes, acetone for 15 minutes, and pure water for 15 minutes in this order. On this substrate, using indium-tin oxide (ITO) target having an SnO₂ content of 10% by weight (indium:tin=95:5 (by molar ratio)), RF magnetron sputtering (conditions: temperature for film formation of 43° C., flow rate of sputtering gas Ar of 12 sccm, RF power of 40 W, and film-forming pressure of 0.4 Pa) was performed to form a thin ITO layer (with a thickness of 30 nm) as a gate electrode. Patterning of the ITO gate electrode was performed using a shadow mask during sputtering.

Next, on the gate electrode, the following gate insulating layer was formed.

Gate insulating layer: a gate insulating layer was provided by performing RF magnetron sputtering vacuum deposition of SiO₂ (conditions: target of SiO₂, temperature for film formation of 54° C., flow rates of sputtering gas Ar/O₂ of 12 sccm/2 sccm, RF power of 400 W, and film-forming pressure of 0.4 Pa) to form a layer having a thickness of 200 nm. Patterning of the SiO₂ gate insulating layer was performed using a shadow mask during sputtering.

On the gate insulating layer, an active layer was provided. Each amorphous oxide prepared according to the Condition 1 to 14 was deposited at a deposition thickness of 50 nm to form an active layer. The deposition conditions of the active layer are in accordance with those described above in “1. Preparation of Active Layer”. Patterning of the active layer was performed, similar to that described above, using a shadow mask during sputtering.

Then, on the above active layer, ITO was deposited at a thickness of 40 nm, as a source electrode and a drain electrode, by RF magnetron sputtering (conditions: temperature for film formation of 43° C., flow rates of sputtering gas Ar of 12 sccm, RF power of 40 W, and film-forming pressure of 0.4 Pa). Patterning of the source electrode and drain electrode was performed using a shadow mask during sputtering. Thereby, TFT elements having a reversed stagger structure with a channel length (L) of 200 μm and a channel width (W) of 1000 μm were prepared.

### 3. Performance Evaluation

(Surface Evenness)

The surface state of the prepared TFT elements was visually observed and sensory evaluated. Evaluation results were classified into the following four rankings:

4: the surface state is even, and anything abnormal is not observed at all;

3: smooth surface unevenness is observed, but a crack is not observed;

2: surface unevenness is observed, and a weak crack is observed;

1: surface unevenness is observed, and a crack that goes through inside the film is observed.

(TFT Performance)

Concerning each of the obtained TFT elements, a current-voltage characteristic curve was prepared by plotting gate voltage (Vg) on the abscissa and drain current (Id) on the ordinate. TFT transfer characteristics at a drain voltage Vd in a saturation region at Vg=0 of 40 V (gate voltage Vg: −20 V>Vg≦40 V) were measured, and electron mobility and ON-OFF ratio of the TFT were evaluated. The measurement of the TFT transfer characteristics was executed using a semiconductor parameter analyzer 4156C (manufactured by Agilent Technologies).

Ids is a value of current at Vg=0 and represents an OFF current (leak current). Ids is preferably 1×10⁻¹⁰ A or less. When Ids exceeds 1×10⁻¹⁰ A, it is not preferred because ON/OFF characteristic of the TFT deteriorates.

—Method of Calculating Electron Mobility—

The electron mobility μ in a saturated region is calculated using the TFT transfer characteristics in accordance with the following equation.

μ=(2L/W×Cₒₓ)×(∂Id^{1/2}/∂Vg)

Herein, L represents a channel length, W represents a channel width, Cₒₓ represents an electrostatic capacity of a gate insulating layer, Id represents a drain current, and Vg represents a gate voltage.

The obtained results are shown in Table 1.

As is clear in Table 1, the TFTs of the invention using an amorphous oxide prepared according to the Condition 3, 6, 8, 9, 11 or 13 exhibit small Ids within a range of 10⁻¹¹ A or more and less than 10⁻¹⁰ A, and high electron mobility. The TFTs using an amorphous oxide prepared according to the Condition 1, 2, or 5 exhibit high electron mobility, but high Ids exceeding 1×10⁻¹⁰ A by far, and unfavorable ON/OFF characteristic. The TFTs using an amorphous oxide prepared according to the Condition 7 or 10 exhibit Ids of 1×10⁻¹⁰ A or less, and exhibit low mobility of 0.8 cm²/Vs or less. Further, in the TFTs using an amorphous oxide prepared according to the Condition 4, 12 or 14, crack occurs on the surface of the active layer, which is not preferred because there is fear of a short in current. But, it is also understood that the TFTs of the invention using an amorphous oxide prepared according to the Condition 3, 6, 9, 11 or 13 exhibit extremely excellent surface evenness.

Comparing sample Nos. 6 and 10 which have an electron carrier concentration of 10¹⁶ cm⁻³ or more and less than 10¹⁷ cm⁻³, the sample No. 6 which has an activation energy of 0.051 eV exhibits excellent mobility such as 5.3 cm²/Vs, whereas the sample No. 10 which has an activation energy of 0.108 eV exhibits low mobility such as 0.8 cm²/Vs. Similarly, when sample Nos. 1, 8 and 9 which have an electron carrier concentration of 10¹⁸ cm⁻³ or more and less than 10¹⁹ cm⁻³ are compared, the sample No. 1 which has an activation energy of about 0 eV exhibits high Ids such as 5×10⁻⁷ A, whereas the sample No. 8 which has an activation energy of 0.043 eV and the sample No. 9 which has an activation energy of 0.058 eV exhibit Ids of 3×10⁻¹¹ A and 2×10⁻¹¹ A, respectively, which are excellent results. From the above results, it is shown that, to obtain a thin film field effect transistor using an amorphous oxide semiconductor which exhibits high field effect mobility and high ON-OFF ratio, it has no meaning in the definition of an absolute value of electron carrier concentration, but it has much meaning in the definition of performance in that electron carrier concentration changes with temperature, that is, the activation energy of electron carrier concentration.

### Example 2

In the configuration of TFT in Example 1, the configuration was changed to that shown in FIG. 2, in which two active layers different in carrier concentration are laminated.

First region of active layer: a layer of the amorphous oxide prepared according to the Condition 3 was provided at a thickness of 40 nm.

Second region of active layer: a layer of the amorphous oxide prepared according to the Condition 1 was provided at a thickness of 10 nm.

The obtained TFT exhibited further excellent performance with Ids of 5×10⁻¹¹ A and electron mobility of 13.8 cm²/Vs.

### Example 3

In the configuration of TFT in Example 1, a co-deposition layer of the following amorphous oxides was used as the active layer.

The amorphous oxide prepared according to the Condition 3 and the amorphous oxide prepared according to the Condition 1 were co-deposited in a ratio of 4:1 (by weight ratio). The deposition thickness was 50 nm.

The obtained TFT exhibited further excellent performance with Ids of 7×10⁻¹¹ A and electron mobility of 12.5 cm²/Vs.

### Example 4

Organic electroluminescence displays were prepared by using the TFT of Example 1 to 3. As a result, a high-gradation imaging display was obtained.

### EXPLANATION OF REFERENCE NUMERALS

1: Substrate
2: Gate electrode
3: Gate insulating layer
4: Active layer
   4-1: Second region
   4-2: First region
5-1: Source electrode
5-2: Drain electrode
6: Insulating layer
81: Organic EL element
82: Cathode
83: Driving TFT
84: Switching TFT
85: Capacitor
86: Common wire
87: Signal wire
88: Scanning wire

What is claimed is:

1. A thin film field effect transistor comprising, on a substrate, at least a gate electrode, a gate insulating layer, an active layer, a source electrode and a drain electrode, wherein the active layer comprises an amorphous oxide, a carrier concentration of the amorphous oxide decreases together with lowering of a temperature thereof from room temperature, and the amorphous oxide has an activation energy of from 0.04 eV to 0.10 eV.

2. The thin film field effect transistor according to claim 1, wherein the amorphous oxide is a complex oxide comprising In and Zn.

3. The thin film field effect transistor according to claim 2, wherein a ratio of In/Zn of the number of In atoms contained in the amorphous oxide to the number of Zn atoms contained in the amorphous oxide, is from 0.1 to 4.0.

4. The thin film field effect transistor according to claim 2, wherein the amorphous oxide further comprises Ga.

5. The thin film field effect transistor according to claim 4, wherein the amorphous oxide comprises a complex oxide of In, Zn and Ga.

6. The thin film field effect transistor according to claim 1, wherein the carrier concentration of the amorphous oxide at room temperature is 6×10¹³ cm⁻³ or more and less than 6×10¹⁵ cm⁻³.

7. The thin film field effect transistor according to claim 1, wherein the active layer comprises at least a first region comprising the amorphous oxide having an activation energy of from 0.04 eV to 0.10 eV, and a second region comprising a second amorphous oxide having an activation energy of less than 0.04 eV, wherein the second region is in contact with the gate insulating layer, and the first region is disposed so as to be electrically connected between the second layer and at least one of the source electrode or the drain electrode.

8. The thin film field effect transistor according to claim 7, wherein the second amorphous oxide comprises a complex oxide of In, Zn and Ga.

9. The thin film field effect transistor according to claim 7, wherein a carrier concentration of the second amorphous oxide at room temperature is 6×10¹⁵ cm⁻³ or more and less than 1×10¹⁰ cm⁻³.

10. The thin film field effect transistor according to claim 1, wherein the substrate is a flexible substrate.

11. An electroluminescence display comprising a light-emitting element comprising, between a pair of electrodes, a thin film layer comprising at least a light-emitting layer, and a thin film field effect transistor for driving the light-emitting element, wherein the thin film field effect transistor is the thin film field effect transistor according to claim 1.
